(19) United States
(12) Patent Application Publication
(10) Pub. No.: US 2014/0261684 A1
(43) Pub. Date: Sep. 18, 2014

(54) SOLAR CELL MODULE

(71) Applicant: SANYO ELECTRIC CO., LTD., Osaka (JP)

(72) Inventors: Wataru SHINOHARA, Gifu (JP); Hiroyuki WATANABE, Aichi (JP)

(73) Assignee: SANYO ELECTRIC CO., LTD., Osaka (JP)

(21) Appl. No.: 14/289,287

(22) Filed: May 28, 2014

Related U.S. Application Data
(63) Continuation of application No. PCT/JP2012/007666, filed on Nov. 29, 2012.

(30) Foreign Application Priority Data
Nov. 30, 2011 (JP) 2011-262359

(51) Int. Cl. H01L 31/048

(52) U.S. Cl. CPC H01L 31/0488
USPC 136/259

(57) ABSTRACT

A solar cell module includes: a front surface glass plate disposed on the light reception side; a rear surface glass plate provided so as to be opposed to the front surface glass plate; a photovoltaic device between the front surface glass plate and the rear surface glass plate; and a filler that fills a space between the front surface glass plate and the rear surface glass plate. The front surface glass plate and the rear surface glass plate have a bonded region which is melt-bonded at peripheral edge sections. Further, an air gap is present between the bonded region and the outer peripheral section of the filler.

### CROSS-REFERENCE TO RELATED APPLICATIONS

This application is based upon and claims the benefit of priority from the prior Japanese Patent Application No. 2011-262359, filed on Nov. 30, 2011, and International Patent Application No. PCT/JP2012/007666, filed on Nov. 29, 2012, the entire content of each of which is incorporated herein by reference.

### BACKGROUND OF THE INVENTION

1. Field of the Invention

Embodiments described herein relate to a solar cell module.

2. Description of the Related Art

As a photoelectric conversion device for converting light energy to electric energy, a so-called solar cell has hitherto been under vigorous development in each field. The solar cell can directly convert light from the sun, which is a clean and inexhaustible energy source, to electricity and has thus been expected as a new energy source.

A solar cell module is used outside, and is thus needed to have a certain degree of strength as a module. Accordingly, there has been devised a solar cell panel formed by sandwiching a photoelectric conversion device between two glasses on the sunlight reception side and the rear surface side.

Incidentally, diffusion of the solar cell requires reduction in power generation cost, and for achieving it, it is effective to prolong lifetime of the photoelectric conversion device. A primary cause of preventing the prolonged lifetime is entry of moisture into the panel. In order to prevent entry of moisture, the peripheral edge end of the above-described solar cell panel is sealed by a sealing material. However, due to its long-term use, the sealing material deteriorates and moisture tends to enter.

### SUMMARY OF THE INVENTION

The present disclosure is made in view of such circumstances, and one non-limiting and exemplary embodiment provides a technique for improving the reliability of a solar cell module. Additional benefits and advantages of the disclosed embodiments will be apparent from the specification and Figures.

The benefits and/or advantages may be individually provided by the various embodiments and features of the specification and drawings disclosure, and need not all be provided in order to obtain one or more of the same.

In one general aspect, the techniques disclosed here feature; a solar cell module includes: a front surface glass plate disposed on the light reception side; a rear surface glass plate provided so as to be opposed to the front surface glass plate; a photovoltaic device between the front surface glass plate and the rear surface glass plate; and a filler that fills a space between the front surface glass plate and the rear surface glass plate. The front surface glass plate and the rear surface glass plate have a bonded section which is melt-bonded at peripheral edge sections. An air gap is present between the bonded section and an outer peripheral section of the filler.

### BRIEF DESCRIPTION OF THE DRAWINGS

FIG. 1 is a plan view of a solar cell module according to a first embodiment, which is seen from the light reception surface side;

FIG. 2 is an A-A sectional view of a vicinity of a terminal box shown in FIG. 1;

FIG. 3 is a main-part enlarged view of an outer edge section of the solar cell module shown in FIG. 1;

FIG. 4 is a view showing a modified example of melt-bonding of a front surface glass plate and a rear surface glass plate;

FIG. 5 is a view showing a modified example of melt-bonding of a front surface glass plate and a rear surface glass plate; and

FIG. 6 is a sectional view showing a structure of a solar cell module according to a second embodiment.

### DETAILED DESCRIPTION

The invention will now be described by reference to the preferred embodiments. This does not intend to limit the scope of the present disclosure, but to exemplify the invention.

Hereinafter, embodiments for carrying out the present disclosure will be described in details with reference to the drawings. It should be noted that in descriptions of the drawings, the same numeral is used for the same constituent element, and any duplicated description will be appropriately avoided.

A scale and a shape of each of layers and sections shown in each of the drawings below have been set in a convenient manner for the sake of facilitating the descriptions, and should not be restrictively interpreted unless otherwise stated.

### First Embodiment

FIG. 1 is a plan view of a solar cell module according to a first embodiment, which is seen from the light reception surface side. FIG. 2 is an A-A sectional view of a vicinity of a terminal box shown in FIG. 1.

This solar cell module 10 is provided with: a front surface glass plate 12 disposed on the light reception side; a rear surface glass plate 14 provided so as to be opposed to the front surface glass plate 12; and a photovoltaic device 16 provided between the front surface glass plate 12 and the rear surface glass plate 14.

A glass plate having a size of 1 m square and a plate thickness of 4 mm is, for example, applied to the front surface glass plate 12. However, this is not restrictive, and one may be applied so long as being suitable for formation of the photovoltaic device 16 and mechanically supporting the solar cell module 10. Light is incident on the solar cell module 10 basically from the front surface glass plate 12 side.

The photovoltaic device 16 is formed on the front surface glass plate 12. The photovoltaic device 16 is formed by laminating a transparent electrode, a photoelectric conversion unit, a rear surface electrode, and the like. As the transparent electrode, there can be used, for example, a film of at least one of, or a film formed by combining a plurality of, transparent conductive oxides (TCO) each obtained by doping tin (Sn), antimony (Sb), fluorine (F), aluminum (Al) or the like into tin oxide (SnO₂), zinc oxide (ZnO), indium tin oxide (ITO) or the like.

Further, examples of the photoelectric conversion unit include an amorphous silicon photoelectric conversion unit (a-Si unit) and a micro crystal silicon photoelectric conversion unit (μc-Si unit). As for the photoelectric conversion unit, there may be formed a structure where a plurality of photoelectric conversion units are laminated, such as a tandem type or a triple type. The rear surface electrode can be made up of a transparent conductive oxide (TCO) and a reflective metal, and formed in a laminate structure of those. As the transparent conductive oxide (TCO), tin oxide (SnO₂), zinc oxide (ZnO), indium tin oxide (ITO) or the like is used, and as the reflective metal, a metal such as silver (Ag) or aluminum (Al) is used.

The rear surface glass plate 14 is provided so as to cover the photovoltaic device 16 formed on the front surface glass plate 12. For example, a glass plate having substantially the same size as that of the front surface glass plate 12 and having a plate thickness of 3.2 mm is applied to the rear surface glass plate 14. However, this is not restrictive.

The front surface glass plate 12 and the rear surface glass plate 14 are melt-bonded at a bonded region R1 of outer peripheral edge regions thereof. The bonded region R1 is provided at a peripheral edge section R2 where the photovoltaic device 16 is not formed on the front surface glass plate 12. The peripheral edge section R2 (region not hatched in FIG. 1) is, for example, provided by removing the photovoltaic device 16 once formed on the front surface glass plate 12 by means of a laser or the like. In order to melt-bonding the front surface glass plate 12 and the rear surface glass plate 14, for example, as shown in FIG. 2, a peripheral section of at least one of the front surface glass plate 12 and the rear surface glass plate 14 is brought into a bent state.

Here, “melt-bonding” can, for example, be regarded as a state where the front surface glass plate 12 and the rear surface glass plate 14 are bonded with each other while part of those is melt. For example, it may be a state where the front surface glass plate 12 and the rear surface glass plate 14 are melt and mixed with each other at the interface between the front surface glass plate 12 and the rear surface glass plate 14.

Next, a description will be given of an extraction channel for electric power generated in the photovoltaic device 16. As shown in FIGS. 1 and 2, first current collection wiring 22 and second current collection wiring 24 are formed so as to extract electric power generated in the photovoltaic device 16. The first current collection wiring 22 is wiring for collecting an electric current from the photovoltaic device 16 divided in parallel, and the second current collection wiring 24 is wiring for connecting from the first current collection wiring 22 to a terminal box 26.

The first current collection wiring 22 is extended onto the rear surface electrode of the photovoltaic device 16. Further, the first current collection wiring 22 is formed for connecting each of positive electrodes, and connecting each of negative electrodes, of a parallel-divided photoelectric conversion layer in the vicinity of each of the end sides of the solar cell module 10. Therefore, the first current collection wiring 22 is extended along a direction orthogonal to a direction of parallel division of the photoelectric conversion layer. In the present embodiment, as shown in FIG. 1, the first current collection wiring 22 is extended to each of the right and left end sides along a vertical direction. Thereby, each of the positive electrodes, as well as each of the negative electrodes, of the serial-connected photovoltaic device 16 is connected in parallel.

Further, an insulating covering material 28 is disposed so as to form electric insulation between the second current collection wiring 24 and the rear surface electrode of the photovoltaic device 16. As shown in FIGS. 1 and 2, the insulating covering material 28 is extended from the vicinity of the first current collection wiring 22 provided along each of right and left end sides of the solar cell module 10 to a disposed position of the terminal box 26 at the center section on the rear surface electrode of the photovoltaic device 16. Further, as shown in FIG. 1, the insulating covering material 28 is extended from the vicinity of each of the right and left first current collection wiring 22 toward the terminal box 26 along a horizontal direction. The insulating covering material 28 is, for example, polyester (PE), polyethylene terephthalate (PET), polyethylene naphthalate (PEN), polyimide, polyvinylidene fluoride or the like, for example. Further, as the insulating covering material 28, for example, one with its rear surface applied with an adhesive in the form of a seal is used.

As shown in FIGS. 1 and 2, the second current collection wiring 24 is extended from the top of each of the right and left first current collection wiring 22 toward the central section of the solar cell module 10 along the top of the insulating covering material 28. By the insulating covering material 28 being sandwiched between the second current collection wiring 24 and the rear surface electrode of the photovoltaic device 16, electric insulation between the second current collection wiring 24 and the rear surface electrode is held. On the other hand, the one end of the second current collection wiring 24 is extended to the top of the first current collection wiring 22, and electrically connected to the first current collection wiring 22. For example, the second current collection wiring 24 is connected electrically to the first current collection wiring 22 by ultrasonic soldering or the like. The other end of the second current collection wiring 24 is connected to an electrode terminal in the below-described terminal box 26.

A region where the front surface glass plate 12 and the rear surface glass plate 14 are opposed to each other is filled with a filler 30. As the filler 30, along with butyl rubber and ethylene-vinyl acetate (EVA), there may be used a material used for caulking such as silicon, a filling resin material such as polyvinyl butylal (PVB), an ethylene resin such as ethylene-ethyl-acrylate (EEA) copolymer, urethane, acryl, an epoxy resin, or the like. Further, as shown in FIG. 2, a below-described air gap 38 is formed between the bonded region R1 and an outer peripheral section of the filler 30.

The rear surface side of the solar cell module 10 is sealed by the rear surface glass plate 14. At this time, the end of the second current collection wiring 24 is pulled out through a through hole 20 provided in the vicinity of a fitted position of the terminal box 26 on the rear surface glass plate 14. Then, the end of the second current collection wiring 24 is electrically connected by soldering or the like to the terminal electrode in the terminal box 26, and a space in the terminal box 26 is filled with an insulating resin 36 such as silicon, and it is sealed. The terminal box 26 is, for example, made to adhere and fitted, by use of silicon or the like, to the vicinity of the through hole 20 for pulling out the end of the second current collection wiring 24.

<Melt-Bonding Method>

Next, there will be described a method for melt-bonding the front surface glass plate 12 and the rear surface glass plate 14.

In melt-bonding the front surface glass plate 12 and the rear surface glass plate 14, as shown in FIG. 2, a peripheral section of at least one of the front surface glass plate 12 and the rear surface glass plate 14 is bent, to bring the peripheral edge sections R2 of the front surface glass plate 12 and the rear surface glass plate 14 into a closely attached state. Then, irradiation is performed with a laser beam 34 from a laser apparatus 32, with its focus set on the contact surfaces of the closely attached peripheral edge sections R2, to perform scanning along four outer peripheral sides of the front surface glass plate 12 and the rear surface glass plate 14.

For example, the laser beam 34 is a femtosecond laser beam. That is, the laser beam 34 is one having a pulse width of not larger than 1 nanosecond. Further, for example, the laser beam 34 has a wavelength with which absorption occurs in at least one of the front surface glass plate 12 and the rear surface glass plate 14. For example, the laser beam 34 has a wavelength of 800 nm. Further, for example, irradiation is performed with the laser beam 34 at an energy density and a scan rate which are high enough to get the front surface glass plate 12 and the rear surface glass plate 14 melted. For example, irradiation is performed with the laser beam 34 with a wavelength of 800 nm, a pulse width of 150 fs, oscillation repetition of 1 kHz and pulse energy of 5 microjoules (μJ) per pulse. Further, for example, the laser beam 34 performs scanning at a scan rate of 60 mm/min. Moreover, irradiation may be performed with the laser beam 34 from either the front surface glass plate 12 side or the rear surface glass plate 14 side.

FIG. 3 is a main-part enlarged view of an outer edge section of the solar cell module 10 shown in FIG. 1. As described above, in the solar cell module 10, the front surface glass plate 12 and the rear surface glass plate 14 have the bonded region R1 which is melt-bonded with the rear surface glass plate 14 or the front surface glass plate 12 as an adjacent member at the peripheral edge section R2. Then, the air gap 38 is formed (present) between the bonded region R1 and an outer peripheral section 30a of the filler 30.

At least part of the peripheral edge sections R2 of the front surface glass plate 12 and the rear surface glass plate 14 is melt-bonded in the solar cell module 10, thereby to improve sealing performance against entry of moisture from the outer edge sections of the front surface glass plate 12 and the rear surface glass plate 14 which are opposed to each other. This can result in improvement in reliability of the solar cell module over a long period of time.

Further, even when the filler 30 expands due to heat generation in the photovoltaic device 16 or heating by the sunlight, the air gap 38 is formed between the bonded region R1 and the outer peripheral section 30a of the filler 30. For this reason, even when the filler 30 expands, the air gap 38 functions as a buffer region, to alleviate an increase in stress due to expansion of the filler 30.

Moreover, when the filler 30 is expanded, the expanded portion is first transformed so as to fill the air gap 38. Hence the filler 30 tends not to reach the vicinity of the bonded region R1, thereby to suppress such a condition as to generate stress to the bonded region R1 in a peeling direction.

Further, the filler 30 and the bonded region R1 that is melt-bonded are separated via the air gap 38, thereby to suppress unnecessary heating of the filler 30 at the time of melt-bonding and suppress deterioration in filler 30.

Moreover, even if moisture enters from the terminal box 26 (the through hole 20 in the rear surface glass plate 14) and moves inside the filler 30, the movement of the moisture is prevented by the air gap 38, and hence the moisture tends not to reach the bonded region R1, thereby suppressing deterioration in sealing performance in the bonded region R1 and improving the bonding reliability.

Furthermore, directly melt-bonding the front surface glass plate 12 and the rear surface glass plate 14 can minimize a portion that can be an entry channel for the moisture into the photovoltaic device 16, to improve the sealing performance of the solar cell module 10 at its outer edge section. Additionally, since the outer peripheral section between the glass plates is sealed using a small number of members, there can be sought reduction in manufacturing cost of the solar cell module 10 by reducing the number of parts and simplifying its assembly process.

It is to be noted that the bonded region R1, for example, is formed over the whole periphery of the outer edge of the front surface glass plate 12 or the rear surface glass plate 14. This can suppress the outside moisture passing through between the front surface glass plate 12 and the rear surface glass plate 14 and entering into the solar cell module 10.

At least one of the front surface glass plate 12 and the rear surface glass plate 14 may be melt-bonded in a bent state with the adjacent member. As thus described, even when at least one of the front surface glass plate 12 and the rear surface glass plate 14 is bent, generated stress is alleviated due to the air gap 38 having been formed.

(Manufacturing Method for Solar Cell Module)

First, the front surface glass plate 12 is prepared which is provided with the photovoltaic device 16, the first current collection wiring 22, the second current collection wiring 24, the insulating covering material 28, and the like. In that state, the filler 30 is disposed so as to cover the photovoltaic device 16. Here, for example in the case of the filler 30 being ethylene-vinyl acetate (EVA) in the form of a sheet, its size is set to such an extent that the air gap 38 is formed between the filler 30 and the bonded region R1 at the time of completing the solar cell module 10. In other words, in the case of the filler 30 in the form of a sheet, it is a square with shorter four sides than the peripheral edge section R2 of the front surface glass plate 12 or the rear surface glass plate 14.

Next, the rear surface glass plate 14 is disposed on the filler 30, and the filler 30 is heat-pressed in a state where the front surface glass plate 12 and the rear surface glass plate 14 are opposed to each other at the peripheral edge sections. The peripheral section of the rear surface glass plate 14 is bent to closely attach the peripheral edge sections of the front surface glass plate 12 and the rear surface glass plate 14 to each other, and irradiation is performed with the laser beam 34 from the laser apparatus 32, with its focus set on the contact surfaces of the closely attached peripheral edge sections R2, to melt-bond the front surface glass plate 12 and the rear surface glass plate 14. This results in manufacturing of the solar cell module 10 formed with the air gap 38 between the filler 30 and the bonded region R1 (cf. FIG. 2).

### Second Embodiment

FIG. 6 is a sectional view showing a structure of a solar cell module according to a second embodiment.

As shown in the sectional view of FIG. 6, a solar cell module 500 according to the second embodiment is configured including: a front surface glass plate 50; a passivation layer 51; a base layer 52; a first conductive type diffusion layer 53; an i-type layer 54; a second conductive type layer 55; a transparent electrode layer 60; a metal layer 57 (57p, 57n); a filler 58; and a rear surface glass plate 59. The passivation layer 51, the base layer 52, the first conductive type diffusion layer 53, the i-type layer 54, the second conductive type layer 55, the transparent electrode layer 60 and the metal layer 57 constitute a photoelectric conversion element.

In the present embodiment, a photovoltaic device 510 is configured including a plurality of photoelectric conversion elements. Further, the photovoltaic device 510 is a rear surface bond-type photovoltaic element, and an electrode for extracting electric power, generated in the photovoltaic element, to the outside is provided only on the primary surface (hereinafter referred to as the rear surface) on the opposite side to the light reception surface. However, the application scope of the present disclosure is not restricted to this, and the photovoltaic device 510 may only be a photovoltaic device in which a plurality of photoelectric conversion elements are disposed on the front surface glass plate 50.

Here, the light reception surface means the primary surface on which light is mainly incident in the photovoltaic element, and specifically, it is the surface on which a large part of light incident on the photovoltaic element is incident. Further, the rear surface means the surface on the opposite side to the light reception surface of the photovoltaic element.

The front surface glass plate 50 mechanically supports the photovoltaic element and also protects a semiconductor layer included in the photovoltaic element from the external environment. Further, as being disposed on the light reception surface side of the photovoltaic element, the front surface glass plate 50 is a material (translucent member) which transmits light with a wavelength band used for power generation in the photovoltaic element and can mechanically support each of the layers such as the base layer 52. As the front surface glass plate 50, for example, a glass plate having translucency is used.

The passivation layer 51 is provided between the front surface glass plate 50 and the base layer 52. The passivation layer 51 plays a role of terminating an uncombined bond (dangling bond) on the front surface of the base layer 52 and some other role, to suppress recombination of carriers on the front surface of the base layer 52. Providing the passivation layer 51 can suppress a loss on the light reception surface of the photovoltaic element due to recombination of carriers on the front surface of the base layer 52.

The passivation layer 51 may, for example, include a silicon nitride (SiN) layer and more has a laminate structure of a silicon oxide (SiOx) layer and silicon nitride. For example, it may be formed in a structure where the silicon oxide layer and the silicon nitride layer are sequentially laminated with respective film thicknesses of 30 nm and 40 nm. As described later, the front surface glass plate 50 is bonded with the photoelectric conversion element via the passivation layer 51.

The base layer 52 is a crystalline semiconductor layer. It should be noted that the crystalline includes not only a monocrystal but also a polycrystal formed by aggregation of a large number of crystal grains. The base layer 52 serves as a power generation layer of the photovoltaic element. Here, the base layer 52 is an n-type crystalline silicon layer added with an n-type dopant. A doping concentration of the base layer 52 may be on the order of 10¹⁶/cm³.

A film thickness of the base layer 52 is desirably a film thickness which is large enough to allow sufficient generation of carriers as the power generation layer, and is not larger than 50 μm.

The base layer 52 and the first conductive type diffusion layer 53 form a first conductive type contact region where each crystalline forms homojunction. The first conductive type diffusion layer 53 is an n-type crystalline silicon layer added with an n-type dopant. The first conductive type diffusion layer 53 is a layer bonded with the metal layer 57 (first electrode 57n), and has a doping concentration higher than that of the base layer 52. A doping concentration of the first conductive type diffusion layer 53 may be set to the order of 10¹⁹/cm³. For example, a film thickness of the first conductive type diffusion layer 53 is made as small as possible in such a range that contact resistance with the metal can be sufficiently low and may, for example, be set to not smaller than 0.1 μm and not larger than 2 μm.

The i-type layer 54 and the second conductive type layer 55 are amorphous semiconductor layers. It is to be noted that the amorphous system includes an amorphous phase or a micro crystal phase where fine crystal grains are disposed in the amorphous phase. In the present embodiment, the i-type layer 54 and the second conductive type layer 55 are amorphous silicon that contains hydrogen. The i-type layer 54 is substantially a genuine amorphous silicon layer. The second conductive type layer 55 is an amorphous silicon layer added with a p-type dopant. The second conductive type layer 55 is a semiconductor layer with a higher doping concentration than that of the i-type layer 54. For example, the i-type layer 54 may intentionally not be doped and a doping concentration of the second conductive type layer 55 may be set to the order of 10¹⁸/cm³. A film thickness of the i-type layer 54 is made small so as to suppress absorption of light as much as possible, whereas the front surface of the base layer 52 is made large to such an extent as to be sufficiently passivated. Specifically, it maybe set to not smaller than 1 nm and not larger than 50 nm, and for example, it is set to 10 nm. Further, a film thickness of the second conductive type layer 55 is made small so as to suppress absorption of light as much as possible and is, on the other hand, made large to such an extent as to make an open circuit voltage of the photovoltaic element sufficiently high. For example, it may be set to not smaller than 1 nm and not larger than 50 nm, and for example, it is set to 10 nm.

As the transparent electrode layer 60, for example, there is used a film of at least one of, or a film formed by combining a plurality of, transparent conductive oxides (TCO) each obtained by doping tin (Sn), antimony (Sb), fluorine (F), aluminum (Al) or the like into tin oxide (SnO₂), zinc oxide (ZnO), indium tin oxide (ITO) or the like. Especially, zinc oxide (ZnO) has advantages of having high translucency, low resistivity, and the like. A film thickness of the transparent electrode layer 60 may be set to not smaller than 10 nm and not larger than 500 nm, and for example, it is set to 100 nm.

The base layer 52, the i-type layer 54 and the second conductive type layer 55 form a second conductive type contact region where the crystalline and the amorphous form heterojunction.

The metal layer 57 is a layer to serve as an electrode provided on the rear surface side of the photovoltaic element. The metal layer 57 is a material configured of a conductive material such as a metal and contains copper (Cu) or aluminum (Al), for example. The metal layer 57 includes the first electrode 57n connected to the first conductive type diffusion layer 53 and a second electrode 57p connected to the second conductive type layer 55. The metal layer 57 may further include an electroplating layer of copper (Cu), tin (Sn) or the like. However, this is not restrictive, and the metal layer 57 maybe gold, silver, some other metal, another conductive material, or one obtained by combining those.

Further, the filler 58 is disposed on the rear surface side of the photovoltaic element, which is then sealed by the rear surface glass plate 59. The filler 58 can be a resin material of EVA, polyimide or the like. Further, a glass plate having substantially the same size as that of the front surface glass plate 50 is applied to the rear surface glass plate 59, and it is thereby possible to prevent entry of moisture into the power generation layer of the photovoltaic device 510 in the solar cell module 500, and the like.

As described above, in the solar cell module 500, the front surface glass plate 50 and the rear surface glass plate 59 have the bonded region R1 which is melt-bonded with the rear surface glass plate 59 or the front surface glass plate 50 as an adjacent member at the peripheral edge section. Then, the air gap 38 is formed between the bonded region R1 and an outer peripheral section 58a of the filler 58.

Moreover, at least one of the front surface glass plate 50 and the rear surface glass plate 59 may be melt-bonded in a bent state with the adjacent member. As thus described, even when at least one of the front surface glass plate 50 and the rear surface glass plate 59 is bent, generated stress is alleviated due to the air gap 38 having been formed.

Although the present disclosure has been described above by referring to each of the above-described embodiments, it is not restricted to each of the above-described embodiments, and any embodiment given by appropriately combining or replacing the configuration of each of the above-described embodiments is also included in the present disclosure. Further, based on knowledge of the skilled person in the art, the combination or the process sequence in each of the embodiments can be appropriately rearranged, and modifications such as a variety of design changes can be added to each of the embodiments, and any embodiment added with such a modification can also be included in the scope of the present disclosure.

In the above-described embodiment, the peripheral edge sections of the front surface glass plate 12 and the rear surface glass plate 14 are directly melt-bonded. However, there are cases where thicknesses of the photovoltaic device 16, wiring and the like disposed inside the solar cell module are large and it is thus difficult to closely attach the front surface glass plate 12 and the rear surface glass plate 14 at the peripheral edge sections. FIGS. 4 and 5 are views each showing a modified example of melt-bonding of the front surface glass plate 12 and the rear surface glass plate 14.

When the gap between the peripheral edge sections of the front surface glass plate 12 and the rear surface glass plate 14 is large, as shown in the sectional view of FIG. 4, a spacer 56 may be formed in the gap, and the spacer 56 may be melted by the above-described laser apparatus 32 to melt-bond the front surface glass plate 12 and the rear surface glass plate 14.

It is preferable to apply, to the spacer 56, a material containing elements capable of melt-bonding the front surface glass plate 12 and the rear surface glass plate 14, such as Si, SiO, SiO₂ or SiOₓ. For example, glass frit may be applied to the outer edge section of the rear surface glass plate 14 by screen printing and then burnt, to form the spacer 56 in a frame form.

Moreover, irradiation maybe performed with the laser beam 34 from both the front surface glass plate 12 side and the rear surface glass plate 14 side. Thereat, in the case of the photovoltaic device 16 (including a silicon substrate) itself being thick as is a crystal system silicon solar cell, or in some other case, a configuration may be formed where the front surface glass plate 12 and the front surface 56a of the spacer 56 are melt-bonded and the rear surface glass plate 14 and the rear surface 56b of the spacer 56 are melt-bonded, as shown in FIG. 5.

Hence the front surface glass plate 12 and the rear surface glass plate 14, which are opposed to each other, can be melt-bonded at the peripheral edge sections while neither the front surface glass plate 12 nor the rear surface glass plate 14 is bent, thereby suppressing such a condition as to generate stress in the peeling direction in the bonded region R1 due to restoring force of the bent glass plate. Further, a crystal system silicon solar cell with a relatively large thickness can be adopted as the photovoltaic device that is disposed between the front surface glass plate 12 and the rear surface glass plate 14.

What is claimed is:

1. A solar cell module comprising:
a front surface glass plate disposed on the light reception side;
a rear surface glass plate provided so as to be opposed to the front surface glass plate;
a photovoltaic device between the front surface glass plate and the rear surface glass plate; and
a filler that fills a space between the front surface glass plate and the rear surface glass plate,
wherein the front surface glass plate and the rear surface glass plate have a bonded section which is melt-bonded at peripheral edge sections, and
an air gap is present between the bonded section and an outer peripheral section of the filler.

2. The solar cell module according to claim 1, wherein the bonded section is formed over whole peripheries of outer edges of the front surface glass plate and the rear surface glass plate.

3. The solar cell module according to claim 1, wherein the bonded section is formed by directly melt-bonding the front surface glass plate and the rear surface glass plate.

4. The solar cell module according to claim 1, wherein at least one of the front surface glass plate and the rear surface glass plate is melt-bonded in a bent state at the bonded section.

5. The solar cell module according to claim 1, further comprising
a spacer member disposed at a peripheral edge section of the front surface glass plate so as to be opposed to the rear surface glass plate,
wherein the bonded section is formed by melt-bonding the spacer member and the peripheral edge section of at least one of the front surface glass plate and the rear surface glass plate.

6. The solar cell module according to claim 2, wherein the bonded section is formed by directly melt-bonding the front surface glass plate and the rear surface glass plate.

7. The solar cell module according to claim 2, wherein at least one of the front surface glass plate and the rear surface glass plate is melt-bonded in a bent state at the bonded section.

8. The solar cell module according to claim 3, wherein at least one of the front surface glass plate and the rear surface glass plate is melt-bonded in a bent state at the bonded section.

9. The solar cell module according to claim 2, further comprising
a spacer member disposed at a peripheral edge section of the front surface glass plate so as to be opposed to the rear surface glass plate,
wherein the bonded section is formed by melt-bonding the spacer member and the peripheral edge section of at least one of the front surface glass plate and the rear surface glass plate.

10. A solar cell module comprising:
a front surface glass plate disposed on the light reception side;
a rear surface glass plate opposed to the front surface glass plate, a peripheral edge of the front surface glass plate and a peripheral edge of the rear surface glass plate being joined together;
a photovoltaic device between the front surface glass plate and the rear surface glass plate; and
a filler filled between the front surface glass plate and the rear surface glass plate, leaving an air gap between the filler and the peripheral edges of the front and rear surface glass plates.

11. The solar cell module according to claim 10, wherein the peripheral edge of the front surface glass plate and the peripheral edge of the rear surface glass plate are joined over whole peripheries of the front surface glass plate and the rear surface glass plate.

12. The solar cell module according to claim 10, wherein the peripheral edge of the front surface glass plate and the peripheral edge of the rear surface glass plate are directly melt-bonded.

13. The solar cell module according to claim 10, wherein at least one of the peripheral edge of the front surface glass plate and the peripheral edge of the rear surface glass plate is melt-bonded in a bent state.

14. The solar cell module according to claim 10, further comprising
a spacer member disposed at the peripheral edge of the front surface glass plate so as to be opposed to the rear surface glass plate,
wherein at least one of the peripheral edge of the front surface glass plate and the peripheral edge of the rear surface glass plate is melt-bonded to the spacer member.

15. The solar cell module according to claim 11, wherein the peripheral edge of the front surface glass plate and the peripheral edge of the rear surface glass plate are directly melt-bonded.

16. The solar cell module according to claim 11, wherein at least one of the peripheral edge of the front surface glass plate and the peripheral edge of the rear surface glass plate is melt-bonded in a bent state.

17. The solar cell module according to claim 12, wherein at least one of the peripheral edge of the front surface glass plate and the peripheral edge of the rear surface glass plate is melt-bonded in a bent state.

18. The solar cell module according to claim 11, further comprising
a spacer member disposed at the peripheral edge of the front surface glass plate so as to be opposed to the rear surface glass plate,
wherein at least one of the peripheral edge of the front surface glass plate and the peripheral edge of the rear surface glass plate is melt-bonded to the spacer member.
